(19) United States
(12) Patent Application Publication
(10) Pub. No.: US 2020/0218148 A1
(43) Pub. Date: Jul. 9, 2020

(54) METHOD FOR FORMING A METAL FILM, AND NANOIMPRINT LITHOGRAPHY MATERIAL

(71) Applicant: Ushio Denki Kabushiki Kaisha, Tokyo (JP)

(72) Inventors: Yohei NAWAKI, Tokyo (JP); Kazuyuki TSURUOKA, Tokyo (JP)

(73) Assignee: Ushio Denki Kabushiki Kaisha, Tokyo (JP)

(21) Appl. No.: 16/737,669

(22) Filed: Jan. 8, 2020

(30) Foreign Application Priority Data
Jan. 9, 2019 (JP) 2019-001638

(51) Int. Cl. G03F 7/00; H05K 3/12; C23C 18/44; C23C 18/16

(52) U.S. Cl. CPC G03F 7/0002; H05K 3/1275; H05K 2203/0108; C23C 18/1641; C23C 18/44

(57) ABSTRACT

The present invention is to solve the problem of residues in nanoimprint lithography without losing the merits thereof, i.e., low cost and high productivity, and provides a metal film formation technique advantageous in pattern accuracy and product reliability over time. A metal film formation method according to the present invention comprises a first step where a nanoimprint lithography material is deposited on an insulating substrate to form an underlayer, a second step where the underlayer is pressed with a mold having protrusions to pattern by nanoimprint lithography, a third step where residues of the underlayer at regions pressed with the protrusions of the mold are evaporated by heating to be removed, and forming a metal film at least on the patterned underlayer. A nanoimprint lithography material according to the present invention contains a catalyst for a metal plating.

### TECHNICAL FIELD

The present invention relates to formation of metal films used for wiring and others.

### TECHNICAL BACKGROUND

Fine-structure metal films are often formed in various products pursuing functions. Metal films for wiring in electronics products are typical examples. To function as a circuit, a metal film needs to be formed in a required pattern on a substrate made of insulator such as glass. A metal film also may be formed for mechanical reinforcement, or may be formed for passivation.

A typical technique to form such a fine-structure metal film is photolithography. In photolithography, a fine-structure metal film is formed by depositing a photosensitive material, i.e., resist, on a metal film, carrying out an exposure and development to form a resist pattern, and then etching the metal film through the resist pattern as a mask. However, such a photolithography technique has a limitation in the productivity improvement, and also has a limitation in the cost reduction, because of a large number of steps therein. Thus, nanoimprinting has been attracting attention as a lower cost and highly productive process. Nanoimprinting is also called “nanoimprint lithography”, NIL.

NIL is a fine processing technique utilizing glass transition of materials. In NIL, an object is pressed with a mold having fine protrusions to transfer the pattern of the protrusions thereto. In this, a surface material of the object transits to a glass state at the glass transition temperature, and the mold has the glass transition temperature higher than that of the surface material of the object. As the object and the mold are heated to a temperature higher than the glass transition temperature of the object and lower than the glass transition temperature of the mold, the object is pressed with the mold to transfer the pattern of the protrusions by the glass transition softening of the surface material of the object.

Relating prior-art patent documents for the present invention are JP2006-327007A, JP2016-083918A, and JPS62-86171A.

A relating prior-art non-patent document for the present invention is “Surface Technology”, Vol. 56, No. 2, 2007, pp. 23-26.

### SUMMARY OF THE INVENTION

NIL has an advantageous aspect respecting to productivity and cost, because the number of steps therein is less than that of photolithography, and the structure of a device to be used therein is comparatively simple. However, NIL has the problem of residual films, being inferior in pattern accuracy. This point is described taking a combined NIL-liftoff process as an example. FIGS. 4A to 4E are schematic views showing the problem of a conventional NIL process.

As shown in FIGS. 4A to 4E, a NIL process may be combined with, for instance, a liftoff process to form a fine-pattern metal film. As shown in FIG. 4A, first of all a resist is coated on a substrate 1 to form a resist film 7. Although “resist”, it does not need to be photosensitive but only needs to be capable of being stripped off from the substrate 1 by a stripper in the liftoff process, because neither exposure nor development is carried out, in contrast to photolithography.

Next, the resist film 7 is patterned by NIL. As shown in FIG. 4B, the resist film 7 is pressed with a mold 3 having a surface on which fine protrusions are formed. As a result, fine depressions and protrusions are formed on the resist film 7 as shown in FIG. 4C. In this, the substrate 1 and the mold 3 are heated at a temperature higher than the glass transition temperature of the resist film 7. Subsequently, as shown in FIG. 4D, a metal film 8 is deposited over the patterned resist film 7 to cover. After lifting off the resist film 7 with a stripper capable of removing the resist from the substrate 1, only the metal film 8 remains in the regions where the resist film 7 has not been deposited, leaving a fine pattern on the substrate 1 as shown in FIG. 4E.

In this combined NIL-liftoff process, residual of the resist after the NIL step is inevitable actually. As magnified in FIG. 4C, resist residues are often film shaped (residual films 71). If the residual films 71 occur, the shape of the metal film 8 after the liftoff step would be much different from one that was expected originally, i.e., much deteriorated in pattern accuracy, because the metal film 8 is also stripped from the regions with the residual films 71 during the liftoff. Even if the resist remains not forming a film but locally, the metal film 8 might be apart, i.e., float up, from the substrate 1 after the liftoff step, much losing adhesive strength to the substrate 1. As a result, the metal film 8 might be peeled off easily over time, and the product reliability would decrease largely, even when the pattern accuracy does not seem deteriorated in appearance. Due to the described situation, the combined NIL-liftoff process has reached a deadlock nevertheless of its convenience.

Though the above description was the problem of residual films or local residues (hereafter referred as “residues” generally) in the combination of NIL with liftoff, NIL has the problem of residues even in other applications. Residues would not matter in a process where only formation of depressions is needed. However, in a process where a layer has to be cut off by pressing it with protrusions of a mold to expose a surface beneath it, e.g., the surface of a substrate, NIL is disadvantageous due to residues.

As a method for solving the problem of residues in NIL, it is considered to carry out a plasma process to remove residues after a NIL process. In NIL, a material that is pressed with a mold, hereafter referred as “NIL material”, is often organic based, e.g., resist, which can be removed by plasma of active species such as oxygen plasma. In the residue removal by a plasma process, a film may be eroded at regions even where it must remain to form a pattern, i.e., regions not having been pressed with protrusions of the mold, due to explosion to the plasma. However, it does not become a problem as far as the film is deposited thick enough in consideration of the erosion during the plasma process.

However, such a plasma process is under vacuum, needing large-scale equipment including a vacuum chamber. Therefore, influence on the cost of the whole manufacturing process is not little. Moreover, it has a problem also in productivity due to a time for vacuum pumping. Therefore, introduction of a plasma process would result in that the merits of NIL, that is, low cost and high productivity, are lost, not being a practicable solution.

The present invention has the object of solving this problem for NIL effectively. In a metal film formation employing NIL, concretely, the invention has the object of solving the problem of residues without losing the merits of low cost and high productivity, and of providing a metal film formation technique advantageous in pattern accuracy and product reliability over time.

To accomplish the object, the present invention provides a method for forming a metal film, comprising a first step where a NIL material is deposited on an insulating substrate to form an underlayer, a second step where the underlayer is pressed with a mold having protrusions to pattern by NIL, a third step where residues of the underlayer at regions pressed with the protrusions of the mold are evaporated by heating to be removed, and forming a metal film at least on the patterned underlayer. In an aspect of the present invention, the thickness of the underlayer in the first step and the heights of the protrusions of the mold used in the second step are 200 nm or more. In another aspect of the present invention, the metal film is deposited by a plating, and the underlayer contains a catalyst for the plating. In another aspect of the present invention, the thickness of the underlayer after the third step is 20 nm or more.

Further to accomplish the object, the present invention provides a NIL material that is deposited on the surface of a substrate and capable of forming a depression-protrusion structure by being pressed with a mold heated to a temperature not less than the glass transition temperature thereof, and contains a catalyst for a metal plating. In an aspect of the invention, the NIL material contains the catalyst and a main component having the glass transition temperature lower than that of the catalyst, and the compounding ratio of the catalyst is 2 to 50 weight percent to the whole including the main component and the catalyst.

### EFFECT OF THE INVENTION

As described later, according to the metal film formation method provided by the present invention, the underlayer can have high pattern accuracy because residues are removed after the NIL step. Therefore, the metal film deposited on the underlayer has high pattern accuracy as well, contributing to the performance improvement of an end product employing this metal film. In this, because residues are removed by heating without generating plasma in the residue removal step, it brings less increase of the cost and brings less decrease of the productivity, nevertheless of the additional step. If the thickness of the underlayer in the first step and the heights of the protrusions of the mold used in the second step are 200 nm or more, it can have the effects that it is required neither to enhance uniformity of the heating temperature, nor to control the heating temperature nor the heating period more accurately. Moreover, if the metal film is deposited by a plating, and if the underlayer material contains a catalyst for this plating, the metal film can be formed at a low cost and high productivity. If the thickness of the underlayer after the third step is not less than 20 nm, more sufficient formation of the metal film is enabled.

According to the NIL material provided by the present invention, it is enabled to form a patterned metal film at a low cost and high productivity, because the metal film can be deposited by the plating only on the underlayer patterned by NIL. The compounding ratio of the catalyst is preferably 2 to 50 weight percent to the whole NIL material, because it is free from the problems that the processability in the NIL may decrease, and that the efficiency of the metal film plating may decrease.

### BRIEF DESCRIPTION OF DRAWINGS

FIGS. 1A to 1G are schematic views of a metal film formation method in the first embodiment.

FIGS. 2A and 2B are schematic views showing the thickness of an underlayer.

FIGS. 3A to 3G are schematic views of a metal film formation method in the second embodiment.

FIGS. 4A to 4E are schematic views showing the problem of a conventional NIL process.

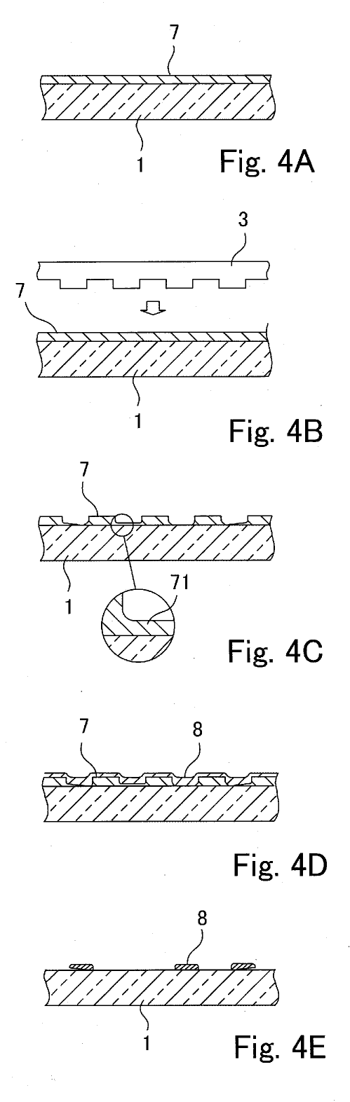

### DETAILED DESCRIPTION

Preferred embodiments of the invention are described next. The major features of the metal film formation methods in the embodiments are to utilize NIL and to solve the problem of residual of a NIL material effectively. In addition, the metal film formation method in the first embodiment adopts a new combination of a NIL process and another process, which has not been attempted conventionally, providing a unique and excellent metal film formation process.

More concretely, the metal film formation method in the first embodiment combines a NIL process and a plating process, and in this, removes residues after the NIL process by heating without plasma generation. In addition, it uniquely combines an electroless plating with the NIL process, and uniquely mixes a catalyst for this plating with a NIL material.

First of all, the NIL material is described. NIL in this embodiment is the thermal NIL. Therefore, the NIL material contains a thermoplastic resin as main component. “Main” in the main component means; it has the glass transition temperature, it is softened when heated to the glass transition temperature, and it is transformed into a depression-protrusion shape when pressed with a mold with protrusions. The main component may be thermoplastic resin such as acrylic resin, e.g., polymethylmethacrylate (PMMA) resin, polyethylene terephthalate (PET) resin, or polycarbonate (PC) resin.

On the other hand, because an electroless plating is to from a desired metal film, the method selects a catalyst that can deposit the metal film by this plating. In this embodiment, a film of precious metal such as gold or platinum is supposedly formed as an example. The self-catalytic method is preferably applied to the electroless plating of such precious metals. In forming a gold film by the self-catalytic method, for instance, a material where gold powder is mixed and dispersed in the main component is used as the NIL material.

In a specific example using PMMA resist as the main component, it is dissolved in an organic solvent such as acetone or isopropyl alcohol. Then, a metal complex is mixed uniformly therein. Subsequently, the organic solvent is thermally evaporated so that the viscosity is adjusted for coating. By this, the NIL material in this embodiment is prepared. Though usually PMMA resists for photolithography contain dissolution inhibitors, one not containing a dissolution inhibitor is used in this example. Otherwise, if a positive type PMMA resist is used, the dissolution inhibitor is resolved in advance by UV irradiation.

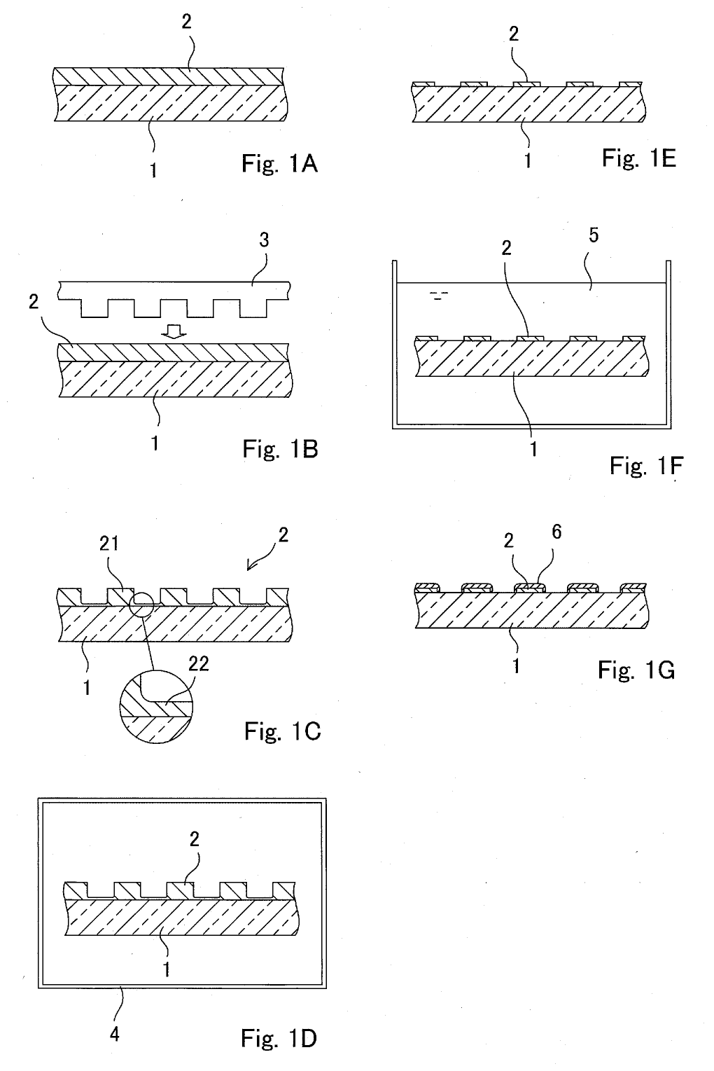

The metal film formation method using the NIL material is described as follows. FIGS. 1A to 1G are schematic views of the metal film formation method in the first embodiment. In the metal film formation method in the first embodiment, a NIL material is initially coated on the surface of an insulating substrate 1 such as glass substrate. Requirements for material of the substrate 1 are; first, not being corroded by the residual solvent in the NIL material nor not being corroded by a plating liquid in a plating step, and second, having the thermal resistance against the heating temperature in a residue removal step. As far as these requirements are satisfied, the substrate 1 may be made of any material. For instance, vitreous silica, other heat resistant glasses, and a kind of heat resistant ceramics can be used. Polyimide resin and other heat resistant resin also can be selected.

(Underlayer Formation Step) As a component of the underlayer, a NIL resin solution may be prepared as follows. 100 g of propyleneglycol monomethylic ether acetate (PGMEA) as solvent is poured in a flask. The temperature of this solvent is increased to 90° C. under the nitrogen atmosphere. A compound liquid containing 16.0 g (0.16 mol) of methyl methacrylate (MMA) of FUJIFILM Wako Pure Chemical Corporation, Japan (FWPCC), 20.7 g (0.24 mol) of methacrylic acid (MAA) of FWPCC, 2.8 g (12 mmol) of 2,2′-azobis (2-methylpropanoic acid methyl, V-601 of FWPCC), and 50 g of PGMEA is dropped spending two hours into the solvent. After finishing dropping, MMA/MAA copolymer is obtained further by stirring them for four hours at 90° C. Subsequently, 25.6 g (0.12 mol) of glycidyl methacrylate (GMA) of FWPCC, 2.1 g of tetraethylammonium bromide (TEAB) of FWPCC, and 50 mg of 4-hydroxy-tetramethylpiperidine-1-oxyl (4-HO-TEMPO) of FWPCC are added to this MMA/MAA copolymer solution, and causes a reaction for eight hours at 90° C. After confirming GMA has disappeared by the reaction on the H-NMR (¹H-nuclear magnetic resonance), a PGMEA resin solution as the NIL resin solution is obtained. A gold complex is mixed with this PGMEA resin solution. By this, the MIL material in this example is obtained. After coating this NIL material on the substrate 1, treatments such as thermal evaporation of the solvent in the resin solution is carried out to solidify the NIL material. As a result, a solidified layer 2 of the NIL material, hereafter referred as “underlayer”, is formed.

(NIL Step) Then, a NIL step is carried out as shown in FIG. 1B. The underlayer 2 is pressed by a mold 3 having protrusions. In this, the substrate 1 and the mold 3 are heated up to not lower than the glass transition temperature of the main component in the NIL material. The underlayer 2 is also heated to the same extent accordingly. By heating and pressing, the shape of the protrusions of the mold 3 is transferred to the underlayer 2 to form depressions thereon. Each shape between the protrusions, i.e., each depression, of the mold 3 is also transferred to the underlayer 2, forming protrusions, hereafter referred as “underlying protrusions”, on the underlayer 2. That is, the underlayer 2 is patterned with the mold 3. After the NIL step, the NIL material remains in the depressions, i.e., regions pressed with the protrusions, producing residues 22, as magnified in FIG. 1C. In this embodiment, it is experimentally learned in advance how high temperature the material should be heated up to be softened enough for NIL, and the material is heated at the learned temperature.

(Residue Removal Step) A residue removal step is carried out after the NIL step. The residue removal step much characterizes this metal film formation method. In the residue removal step in this embodiment, the removal is carried out by heating with no plasma generation. As shown in FIG. 1D, concretely, the substrate 1 on which the patterned underlayer 2 has been formed is loaded into a heat furnace 4 and heated therein at a predetermined temperature for a predetermined period. By this, the residues 22 are removed as shown in FIG. 1E. The predetermined temperature in the residue removal step is a temperature where the main component of the NIL material evaporates. Evaporation here is not only via liquid phase but may be direct evaporation, i.e., sublimation.

The predetermined period in the residue removal step is a period where all residues 22 existing in the depressions evaporate, and where the sufficiently thick NIL material remains after finishing heating. In other words, though the NIL material forming the protrusions is also heated to evaporate in the residue removal step, the heating temperature and the heating period are determined so that it can remain at a sufficient thickness (height), not evaporating completely. The heating temperature in this is higher than the heating temperature in the NIL step, i.e., a temperature higher than the glass transition temperature of the NIL material. As an example of the heat condition, the heating temperature may be 500° C., and the heating period may be 30 minutes, when the main component of the NIL material is PMMA resist. The remaining underlying protrusions 21 form the patterned underlayer 2. The underlayer 2 having a desired nano-porous structure is obtained on the glass substrate 1 by thermally decomposing the NIL resin solution during the evaporation of the residues 22 as described.

(Reduction Step) The substrate 1 on which the underlayer 2 has been formed is dipped in a NaBH₄ solution (concentration: 2 g/L, temperature: 50° C.) for two minutes. By this step, gold ions contained in the underlayer 2 are reduced, and the catalyst (gold) is given to whole the surfaces including the inner wall surfaces of pores.

(Plating Step) After the residue removal step and reduction step, a plating step is carried out. Because the electroless plating is adopted in this embodiment, the substrate 1 having the patterned underlayer 2 is dipped in a plating liquid 5 in a predetermined period for the plating as shown in FIG. 1F. As a result, a metal film 6 is deposited only on the patterned underlayer 2 containing the catalyst, as shown in FIG. 1G. Because this embodiment adopts the electroless and self-catalyst plating, the plating liquid used therein is a solution containing the material of a metal film to form.

The described electroless plating is an example, to which the invention is not limited. In deposing a gold film, for instance, a non-cyanide type is preferable. A plating liquid may be a mixture of auric chloride acid (hydrate liquid) such as sodium aurichloride acid, sodium thiosulfate as complexing agent, and thiourea as reducing agent. Ammonium chloride is further added as pH regulator. The pH may be 4.0, and the plating temperature may be 60° C. A specific compounding ratio is disclosed in JPS62-86171A. The condition of a self-catalyst plating using tiopronin-gold complex is disclosed in the paragraph 0082 of JP2016-83918A, being able to adopt. In this self-catalyst gold plating, gold appears only on regions where the gold catalyst exists. Therefore, the gold film 6 is formed only on the patterned underlayer 2 as shown in FIG. 1G. In a word, the gold film 6 is formed tracing the pattern established in the NIL step.

Whereas the gold film was described as an example, film formation of platinum and other metals is basically the same. In a self-catalyst plating of platinum, a platinum compound such as Pt(NH₃)2(NO₂)₂ is used, and hydrazine is used as reducing agent. The compounding condition of a plating liquid is disclosed in, for instance, “Surface technology” Vol. 56, No. 2, 2007, and pp. 23-26. As for self-catalyst plating processes of metals other than gold and platinum, kinds of suitable conditions are disclosed. Plating liquids for gold, platinum and others, which are commercially available, can be chosen adequately to use.

The displacement electroless plating, which in known as another type of electroless plating than the self-catalyst plating, also may be adopted. In depositing a gold film by the displacement electroless plating, for instance, because nickel is used for the underlying catalyst, nickel is mixed in the NIL material. Then, the underlayer is patterned similarly by NIL, and put in a plating bath after removing residues. As a result, a gold film is deposited only on the patterned underlayer.

According to the described metal film formation method in this embodiment, though NIL is utilized in pattering the underlayer 2, the underlayer 2 can have high pattern accuracy because residues are removed after the NIL step. Therefore, the metal film 6 formed on the underlayer 2 has high pattern accuracy as well, much contributing to the performance improvement of an end product employing this metal film. Because residues are removed by heating without plasma generation in the residue removal step, increase of the cost is little, and it is free from the problem of productivity decrease, nevertheless of the additional step.

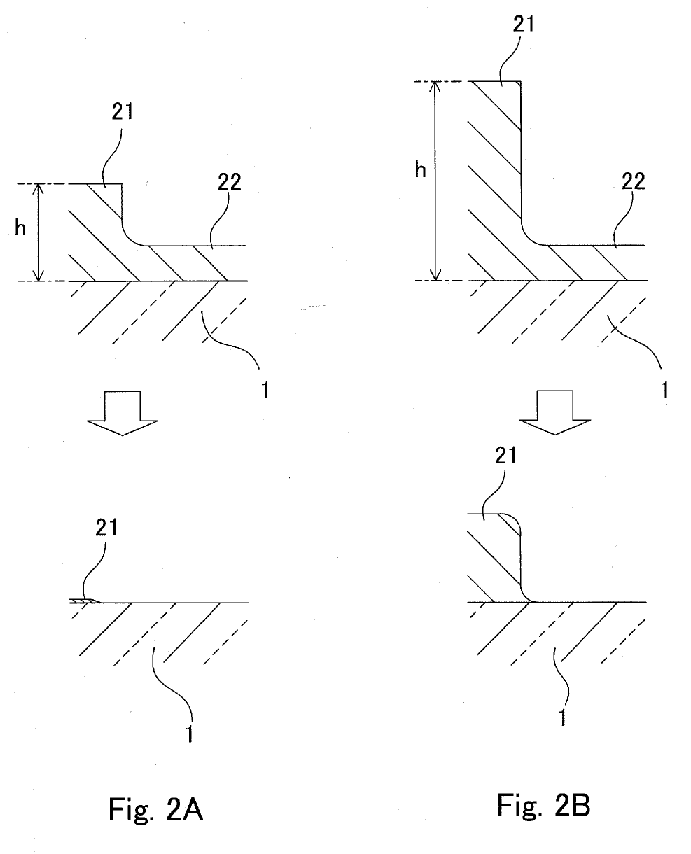

In the residue removal without plasma generation, still it should be noted that it has to be avoided to remove the whole underlayers 2 with residues. Therefore, it is necessary to control the heating temperature and the heating period. Accompanied by this, it also should be noted to coat the underlayer 2 thickly to some extent on the substrate 1. This point is described referring to FIGS. 2A and 2B. FIGS. 2A and 2B are schematic views showing the thickness of the underlayer 2.

In FIGS. 2A and 2B shown underlayers 2 just when the NIL step is finished. As shown in FIGS. 2A and 2B, the NIL material on the regions between the underlying protrusions 21, i.e., regions pressed with the protrusions of the mold 3, remain to form residues 22 just when the NIL step is finished.

In this case, if the heights h of the underlying protrusions 21 are low as shown in FIG. 2A, not only the residues 22 but also the underlying protrusions 21 could be removed by evaporation while those are heated in the the residue removal step. If the heating temperature uniformity in the heat furnace is a little insufficient, for instance, the underlying protrusions 21 could be overheated locally and thus evaporate completely or almost completely. By contrast, if the heights h of the underlying protrusions 21 are high enough as shown in FIG. 2B, the underlying protrusions 21 do not evaporate completely nor almost completely while heated in the residue removal step, remaining with desired heights.

What regulates the heights of the underlying protrusions 21 is the heights of the protrusions of the mold 3 used in the NIL step. Since the heights of the underlying protrusions 21 are the heights of the protrusions of the mold 3 plus the thickness of the residues 22, the heights of the protrusions of the mold 3 are the heights of the underlying protrusions 21 minus the thickness of the residues 22. The heights of the underlying protrusions 21 minus the thickness of the residues 22 must be margins of the underlying protrusions 21 in removing the residues 22 by heating without plasma generation. According to an investigation by the inventors, the heights of the underlying protrusions 21 minus the thickness of the residues 22, i.e., the heights of the protrusions of the mold 3, is preferably 200 nm or more. In a kind of NIL, pressing with protrusions of a mold may be incompletely, that is, bottoms of depressions may float up from the underlayer 2. In this case, its floating height has to be added to the heights of the protrusions of the mold 3.

In any case, by providing adequate heights for the protrusions of the mold 3, the underlying protrusions 21 can have sufficient heights h, and as a result, the residues 22 can be removed completely as the underlying protrusions 21 remain with enough heights. Even if the heights of the protrusions of the mold 3 are lower than 200 nm, it is possible to remove residues 22 completely as the underlying protrusions 21 remain with enough heights, by improving the heating temperature uniformity in the residue removal step, or by controlling the heating temperature and the heating period more accurately. In other words, the 200 nm or more heights of the protrusions of the mold 3 have the effect that it is required neither to make the heating temperature uniformity higher, nor to control the heating temperature nor the heating period more accurately.

The heights of the underlying protrusions 21 after the residue removal step, i.e., the thickness of the underlayer 2, is preferably 20 nm or more. In this embodiment, after removing residues a metal film 6 is formed on the underlying protrusions 21 by reaction with a catalyst necessary for an electroless plating. Low heights of the underlying protrusions 21 after removing residues may cause shortage of the catalyst necessary for the electroless plating, making the sufficient metal film formation impossible. Therefore, the heights of the underlying protrusions 21 after removing residues are preferably 20 nm or more.

In the described metal film formation method, the catalyst added to the NIL material is often a metal, and usually has the boiling point or sublimation point higher than that of the main component. Therefore, after the residue removal step only particles of the catalyst could remain at regions where residues 22 existed. In this case, an adequate cleaning process is added, washing out the residual catalyst. In this cleaning, the pattern of the remaining underlayer 2 may not be deformed. When the catalyst has the boiling point or sublimation point higher than that of the main component, the compounding ratio (concentration) of the catalyst in the remaining underlayer 2 could become higher than that before the residue removal step. This means the function of the catalyst is enhanced in the plating step, and thus means a metal film with a sufficient thickness can be formed efficiently.

In the NIL material, the compounding ratio of the catalyst (ratio before the residue removal step) is preferably 2 to 50 weight percent to the whole. The whole in this is the whole including the main component and the catalyst, not including either a solvent dissolving the main component nor a solvent for a catalyst paste. A higher compounding ratio of the catalyst is preferable in view of improving the efficiency in the plating. However, an increased ratio of the catalyst, which is often a metal or metallic compound, may worsen the processability in NIL. Therefore, the compounding ratio of the catalyst is preferably not more than 50 weight percent. If the catalyst compounding ratio is less than 2 weight percent, the plating efficiency in the plating step may decrease due to small amount of the catalyst, even though it could be increased in the residue removal step. Therefore, the catalyst compounding ratio is preferably 2 weight percent or more.

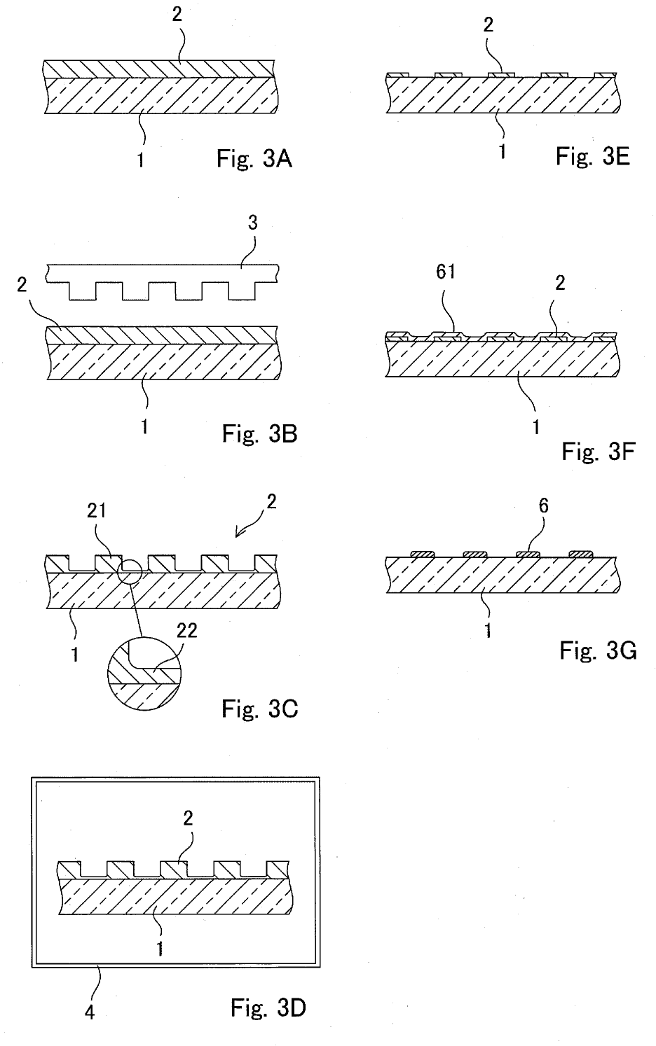

A metal film formation method in the second embodiment is described next. FIGS. 3A to 3G are schematics views of the metal film formation method in the second embodiment. The liftoff is adopted in the second embodiment whereas the metal film 6 was formed on the underlayer 2 by plating in the first embodiment. In this embodiment, concretely, the NIL material or the main component of the NIL material is a resist removable by a stripper for the liftoff. Even though a resist, it does not need to be photosensitive but only needs to have a certain glass transition temperature, because it is patterned by NIL.

In depositing a metal film according to the method in the second embodiment, the described NIL material is coated on an insulating substrate 1, forming an underlayer 2 (FIG. 3A). The NIL step is carried out next. The NIL material is pressed by a mold 3 as heated at a temperature higher than the glass transition temperature of the NIL material, and thus the pattern of protrusions of the mold 3 is transferred to the underlayer 2 (FIG. 3B). As a result, the underlayer 2 is patterned (FIG. 3C). Subsequently, the substrate 1 is loaded into a heat furnace 4 to carry out the residue removal step as well (FIG. 3D). As a result, residues 22 of the underlayer 2 are removed (FIG. 3E).

Next, a metal layer 61 is deposited covering the region of the patterned underlayer 2 and the exposed regions without the underlayer 2 (FIG. 3F). A desired process such as sputtering or chemical vapor deposition (CVD) can be adopted to form the metal layer 61. Subsequently, a liftoff step is carried out. The resist (underlayer 2) is removed by a resist stripper. In this, portions of the metal layer 61 overlapping the underlayer 2 are removed together, and thus the metal film 6 is formed on the substrate 1 with the pattern of the regions where the underlayer 2 did not exist.

In this second embodiment as well, the pattern accuracy of the underlayer 2 after the NIL step is improved because the residues 22 are removed in the residue removal step. Therefore, this method increases the pattern accuracy of the residual metal layer 61, i.e., the patterned metal film 6, which remains after the liftoff step. In this, because the residues 22 are removed by heating without plasma generation in the residue removal step, it is accompanied neither by large increase of the process cost nor by large decrease of the productivity.

In contrast to the first embodiment, the metal layer 61 is formed by a method using vacuum such as sputtering or CVD in the second embodiment. Compared with these deposition processes, deposition by plating is cheap and highly productive because it does not need a time either for evacuation nor for ventilation. Still, the second embodiment can adopt any material for the metal layer 61, whereas in the first embodiment it is limited to a material capable of being deposited by an electroless plating using a catalyst. Therefore, the second embodiment is advantageous in its wider applicability.

The metal films formed in the described embodiments can be utilized for products performing various functions. For instance, those may be utilized as circuits in various chip elements, otherwise may be utilized as electrodes for various tests. If the metal film formation method is applied for sensing where an electrode contacts with a sample, deposition of a metal film of chemically stable material such as gold or platinum for the electrode has the effect of no contamination of the sample. Metal films may be applied to perform optical functions. Concretely, metal films may be formed in applications such as diffraction gratings, polarizers, and photoelectric conversion (photodetection) elements.

The metal film 6, which was formed only on the patterned underlayer 2, may be formed on other regions as well. As in the second embodiment, a metal film may be formed the whole area including the underlayer 2 in the middle of a process. Whereas the metal film 6 finally remained in the regions without the underlayer 2 in the second embodiment because it adopted the liftoff step, a metal film may remain covering the whole area for some reason. That is, an application may adopt the structure where a metal film is formed covering the whole area of the underlayer 2 for a required function. Otherwise, an application may adopt a process where a metal film is formed only on the underlayer 2 and a certain region out of the underlayer 2, not being formed on other regions.

In the described embodiments, the heating was in the heat furnace 4. This is concretely heating by heated-air circulation in a closed room. Otherwise, it may be heating by placing the substrate 1 on a hot plate or may be irradiance heating.

In the first embodiment, the catalyst existed only on the underlayer 2, with which a metal film 6 was plated directly, and as a result, the patterned film (plating film) 6 was formed. Such a technique may be called “direct plating”. Whereas usually a non-patterned film, which is formed by plating, is patterned by such a process as photolithography, a patterned metal film is formed by plating directly in the direct plating.

Though the substrate 1 was an insulator in described each embodiment, the substrate 1 may be conductive, not needing to be an insulator in practicing the residue removal step. For a conductive substrate, not the electroless plating but an electro plating may be adopted.

What is claimed:

1. A method for forming a metal film, comprising
a first step where a nanoimprint lithography material is deposited on an insulating substrate to form an underlayer,
a second step where the underlayer is pressed with a mold having protrusions to pattern by nanoimprint lithography,
a third step where residues of the underlayer at regions pressed with the protrusions of the mold are evaporated by heating to be removed, and
forming a metal film at least on the patterned underlayer.

2. A method for forming a metal film as claimed in the claim 1, wherein the thickness of the underlayer in the first step and the heights of the protrusions of the mold used in the second step are 200 nm or more.

3. A method for forming a metal film as claimed in the claim 1, wherein the metal film is deposited by a plating, and the underlayer contains a catalyst for the plating.

4. A method for forming a metal film as claimed in the claim 2, wherein the metal film is deposited by a plating, and the underlayer contains a catalyst for the plating.

5. A method for forming a metal film as claimed in the claim 3, wherein the thickness of the underlayer after the third step is 20 nm or more.

6. A method for forming a metal film as claimed in the claim 4, wherein the thickness of the underlayer after the third step is 20 nm or more.

7. A nanoimprint lithography material, which is deposited on a surface of a substrate and capable of forming a depression-protrusion structure by being pressed with a mold heated to a temperature not less than the glass transition temperature thereof, containing a catalyst for a metal plating.

8. A nanoimprint lithography material as claimed in the claim 7, further containing a main component having the glass transition temperature lower than that of the catalyst, wherein the compounding ratio of the catalyst is 2 to 50 weight percent to the whole including the main component and the catalyst.
